(19) United States
(12) Patent Application Publication
(10) Pub. No.: US 2023/0296676 A1
(43) Pub. Date: Sep. 21, 2023

(54) SYSTEM FOR ASSESSMENT OF BATTERY CELL DIMENSIONAL VARIATION

(71) Applicant: WILDCAT DISCOVERY TECHNOLOGIES, Inc., San Diego, CA (US)

(72) Inventors: David J. Brecht, San Diego, CA (US); Justin J. Dutton, San Diego, CA (US); Deidre A. Strand, San Diego, CA (US); Peter Lamp, Landsberg am Lech (DE)

(73) Assignee: WILDCAT DISCOVERY TECHNOLOGIES, Inc., San Diego, CA (US)

(21) Appl. No.: 17/695,765

(22) Filed: Mar. 15, 2022

(51) Int. Cl. G01R 31/36; G01B 5/00

(52) U.S. Cl. CPC G01R 31/3644; G01B 5/0004

(57) ABSTRACT

A system for assessment of dimensional variation of an electro-chemical battery cell during charge/discharge cycling, including a test fixture configured to position thereon a battery cell. The test fixture includes a pressure plate configured to apply a force to the battery cell. The test fixture also includes a reaction plate disposed parallel to the pressure plate and configured to sandwich the battery cell between the reaction plate and the pressure plate. The test fixture additionally includes an elastic member assembly configured to facilitate adjustment of the force applied to the battery cell. The system additionally includes an electronic hardware device configured to regulate an electrical current applied to the battery cell. The system further includes a contact displacement sensor configured to detect change in the battery thickness.

### INTRODUCTION

The present disclosure relates to a system for assessment of dimensional variation of electro-chemical battery cells during charge/discharge cycling.

Electro-chemical battery cells may be broadly classified into primary and secondary batteries. Primary batteries, also referred to as disposable batteries, are intended to be used until depleted, after which they are simply replaced with new batteries. Secondary batteries, more commonly referred to as rechargeable batteries, employ specific chemistries permitting such batteries to be repeatedly recharged and reused, therefore offering economic, environmental and ease-of-use benefits compared to disposable batteries. Electro-chemical batteries may be used to power such diverse items as toys, consumer electronics, and motor vehicles.

Electro-chemical batteries are structurally and dimensionally dynamic during common use. Typically, a secondary cell's thickness undergoes changes during the charge/discharge cycles. In lithium ion and polymer cells, the battery thickness generally changes during charge/discharge cycles for three reasons—(i) expansion and contraction of host materials due to lithium intercalation, (ii) electrode volume increase caused by irreversible reaction deposits, and (iii) dead volume and pressure changes within the cell case depending on battery structure and construction. Such dimensional changes may be an important consideration in the design of battery or battery module casing, and overall battery packaging.

### SUMMARY

A system for assessment of dimensional variation of an electro-chemical battery cell during charge/discharge cycling, including a test fixture configured to position thereon a battery cell. The test fixture includes a pressure plate configured to apply a force to the battery cell. The test fixture also includes a reaction plate disposed parallel to the pressure plate and configured to sandwich the battery cell between the reaction plate and the pressure plate. The test fixture additionally includes an elastic member assembly configured to facilitate adjustment of the force applied, via the pressure plate, to the battery cell. The system additionally includes an electronic hardware device configured to regulate an electrical current applied to the battery cell. The system further includes a contact displacement sensor configured to detect change in the battery thickness.

The system may also include a support plate mounted to the reaction plate. In such an embodiment, the contact displacement sensor may be mounted to the support plate.

The support plate may define an aperture. The contact displacement sensor may include a probe extending through the aperture and contacting the pressure plate.

The test fixture may also include a plurality of posts configured to set a separation distance between the support plate and the reaction plate and guide movement of the pressure plate relative to the reaction plate.

The elastic member assembly may include a retention plate having a plurality of pockets configured to accept a variable quantity of elastic members and thereby adjust the applied force.

The elastic member assembly may include a plurality of coil springs disposed between the pressure plate and the support plate

The electronic hardware device may include a potentiostat.

The system may also include a load sensor configured to detect the applied force and an electronic processor. The electronic processor may be configured to receive a first signal from the electronic hardware device indicative of the applied electrical current, a second signal from the load sensor indicative of the applied force, and a third signal from the contact displacement sensor indicative of the detected battery thickness. The electronic processor may be further configured to generate a data file representing a correlation between the applied electrical current, the applied force, and the detected battery thickness.

The system may additionally include an environmental chamber configured to position the test fixture therein and expose the test fixture to predetermined temperature. The environmental chamber may include a temperature sensor configured to detect actual temperature inside the environmental chamber.

The electronic processor may be additionally in communication with the temperature sensor and be further configured to receive a fourth signal from the temperature sensor. In such an embodiment, generated data file may additionally represent a correlation between the applied electrical current, the applied force, the detected battery thickness, and the detected actual temperature.

The above features and advantages, and other features and advantages of the present disclosure, will be readily apparent from the following detailed description of the embodiment(s) and best mode(s) for carrying out the described disclosure when taken in connection with the accompanying drawings and appended claims.

### BRIEF DESCRIPTION OF THE DRAWINGS

FIG. 1 is a schematic cut-away view of a pouch battery cell having anode and cathode electrodes.

FIG. 2 is a schematic perspective view of a system for assessment of dimensional variation of an electro-chemical battery cell (such as the battery cell shown in FIG. 1) during charge/discharge cycling, including an embodiment of a test fixture configured to position thereon the battery cell, according to the disclosure.

FIG. 3A is a schematic close-up perspective view of another embodiment of the test fixture employed in the system for assessment of dimensional variation of an electro-chemical battery, according to the disclosure.

FIG. 3B is a schematic close-up side view of the embodiment of the test fixture shown in FIG. 3A.

FIG. 3C is a schematic close-up perspective view of the embodiment of the test fixture shown in FIG. 2, according to the disclosure.

FIG. 4 is a schematic close-up perspective view of a contact displacement sensor configured to detect changes in the thickness of the battery cell, specifically a high-resolution contact displacement sensor, according to the disclosure.

FIG. 5 is a schematic close-up perspective view of a battery installation fixture for the embodiment of the test fixture shown in FIGS. 3A and 3B, according to the disclosure.

FIG. 6 is a schematic close-up perspective view of the test fixture arranged on the battery installation fixture shown in FIG. 5.

FIG. 7 is a schematic close-up perspective view of a force-adjustment fixture configured to adjust a force applied to the battery cell by the test fixture shown in FIGS. 3A and 3B, according to the disclosure.

### DETAILED DESCRIPTION

Those having ordinary skill in the art will recognize that terms such as “above,” “below,” “upward,” “downward,” “top,” “bottom,”, “left”, “right”, etc., are used descriptively for the figures, and do not represent limitations on the scope of the disclosure, as defined by the appended claims. Furthermore, the teachings may be described herein in terms of functional and/or logical block components and/or various processing steps. It should be realized that such block components may be comprised of a number of hardware, software, and/or firmware components configured to perform the specified functions.

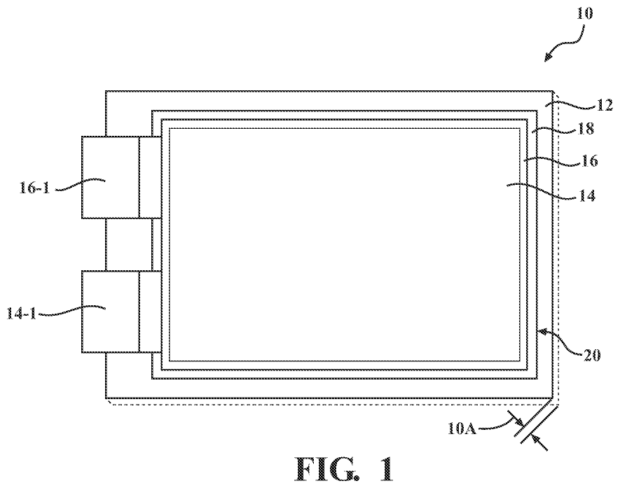

Referring to FIG. 1, a pouch type battery cell 10 is depicted. Although a pouch cell is shown, the battery cell 10 may have a different geometry, such as a cylindrical or “button” shape. The battery cell 10 generates electrical energy through heat-producing electro-chemical reactions. Additionally, the battery cell 10 may be configured ether as a primary, i.e., disposable, energy cell or a secondary i.e., rechargeable, energy storage cell. As a primary energy cell, the battery cell 10 may be configured, for example, as a Lithium, Nickel Cadmium, or Nickel Metal Hydride cell. As a secondary energy cell, the battery cell 10 may be configured, for example, as a Lithium ion (Li-ion) cell. The battery cell 10 may, for example, be employed for operating toys, consumer electronics, and motor vehicles.

Specifically, FIG. 1 schematically depicts an exemplary embodiment of the battery cell 10 configured as a pouch cell in a cut-away state to illustrate arrangement of the cell's internal components. As shown, an assembled battery cell 10 may be constructed as a pouch cell, which includes a sealed enclosure or pouch 12. Walls of the pouch 12 are typically constructed from two layers of polymer sandwiching an aluminum layer. A negative electrode or anode 14 and a positive electrode or cathode 16 are packaged and retained within the pouch 12. The anode 14 is in contact with a negative terminal 14-1, while the cathode 16 is in contact with a positive terminal 16-1. The anode 14 is physically isolated from the cathode 16 by a separator 18. The anode 14 and the cathode 16 are typically immersed in an electrolyte 20 formulated to conduct ions as the battery cell 10 discharges, and also when the battery charges, as in the case of a rechargeable battery. The battery cell 10 is designed and assembled to maintain physical integrity and reliable performance under a variety of external and internal stresses, such as due to vibration and temperature fluctuations. Multiple pouch cells, such as the cell depicted in in FIG. 1, may be stacked together for enhanced performance in specific applications.

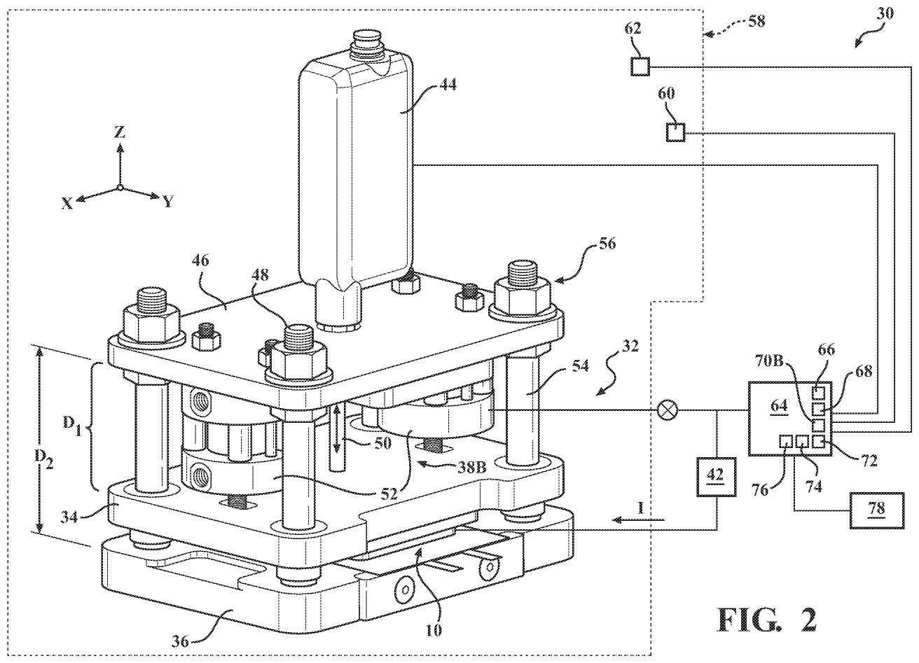

During charge and discharge, electro-chemical batteries, such as the battery cell 10, respectively expand and contract. Specifically, the battery's thickness 10A (schematically shown in FIG. 1), and thus the battery's volume, undergoes a cyclical change. In Lithium-ion batteries, the change is generally caused by lithium ion intercalation into host materials, i.e., graphite and lithium transition metal oxide and resultant lattice expansion and contraction. The extent of dimensional change of the battery cell 10 may be additionally subject to the particular battery's construction, geometry, and materials used. FIG. 2 illustrates a system 30 configured for assessment of dimensional variation, such as the change in the thickness 10A, of the battery cell 10 during charge/discharge cycling.

The system 30 includes an adjustable test fixture 32, which may be arranged in an environmental chamber, to be discussed in detail below. The test fixture 32 is configured to position the battery cell 10 substantially in an X-Y plane, such that the battery thickness 10A is arranged along a Z-direction. The test fixture 32 includes a pressure plate 34 configured to apply a force Fₚ to the battery cell 10 in the Z-direction. The test fixture 32 also includes a reaction or base plate 36 disposed parallel to the pressure plate 34 and configured to sandwich the battery cell 10 between the reaction plate and the pressure plate. Each of the pressure plate 34 and the reaction plate 36 may be constructed from metal, such as aluminum, or an engineered plastic.

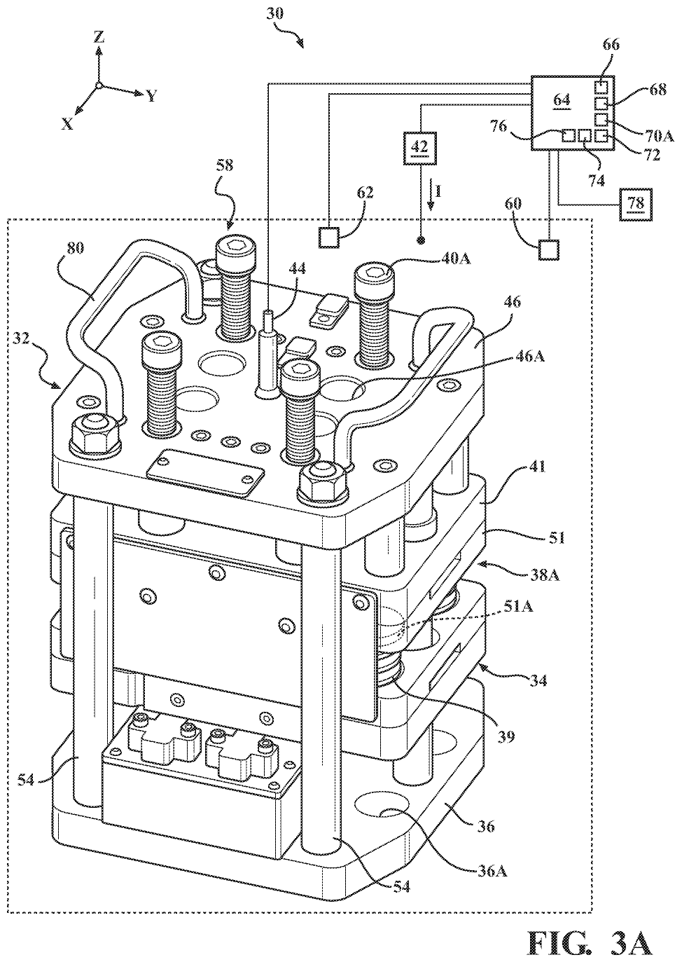

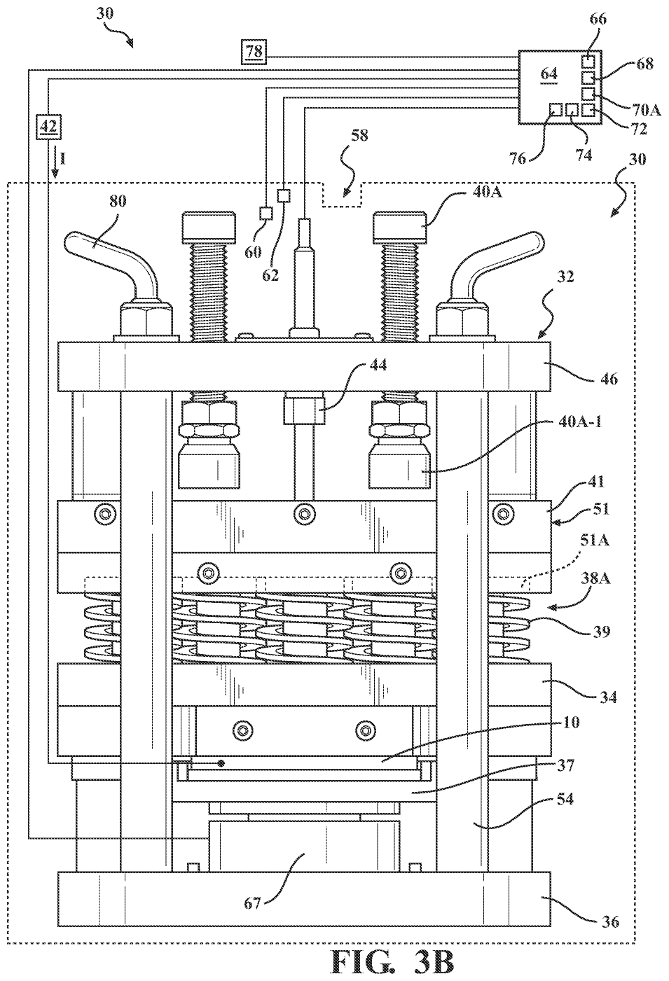

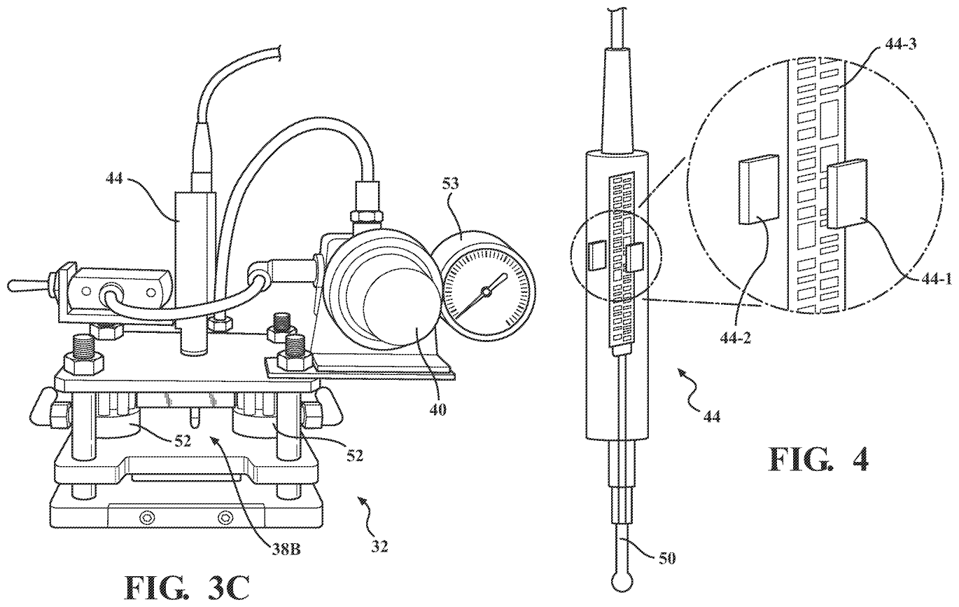

As shown in FIGS. 3A and 3B, the battery cell 10 may be nestled in a battery cell holder 37. The test fixture 32 shown in FIGS. 3A and 3B may also include an elastic member assembly 38A configured to facilitate adjustment of the Fₚ applied, via the pressure plate 34, to the battery cell 10 nestled in the battery cell holder 37. The elastic member assembly 38A may include a plurality of elastic members or coil springs 39. The subject elastic member assembly 38A may also include one or more locking screws 40A (shown in FIGS. 3A and 3B) configured to be tightened or torqued to set and hold compression of the elastic member(s) 39 via a load plate 41. The load plate 41 is intended to be constructed from a rigid and tough material, such as metal or an engineered plastic, to withstand the force Fₚ. The locking screws 40A may include swivel-mounted end contacts 40A-1 configured to adapt to dimensional, e.g., surface parallelism and thickness, tolerances of the load plate 41. Alternatively, as shown in FIG. 3C, the test fixture 32 may include a pneumatic mechanism 38B configured to vary the force Fₚ applied, via the pressure plate 34, to the battery cell 10. The pneumatic mechanism 38B may include a regulator 40B (shown in FIG. 3C) configured to adjust the applied force Fₚ.

The test fixture 32 also includes an electronic hardware device 42 (shown in FIG. 2) configured to regulate an electrical current I applied to the battery cell 10. The electronic hardware device 42 may include a potentiostat configured to operate through a software package programmed into an electronic controller, to be described in detail below. In general, a potentiostat is a control and measuring device. The employed potentiostat includes an electric circuit, which controls a potential across the battery cell 10 by sensing changes in the cell's resistance. The potentiostat varies the electrical current I supplied to the system accordingly to the sensed resistance—a higher resistance will result in a decreased current, while a lower resistance will result in an increased current, to keep the voltage constant across the battery cell 10.

As shown in FIGS. 2 and 3A-3C, the test fixture 32 also includes a contact displacement sensor 44 configured to track changes in the battery thickness 10A via detection of displacement of the pressure plate 34 in the Z-direction. The sensor 44 may be an electrical transformer, and specifically a linear variable differential transformer or linear variable displacement transducer (LVDT) employing multiple solenoidal coils and a sliding probe (not shown) to measure linear displacement and thickness 10A of the battery cell. Alternatively, the sensor 44 may be configured as a high-resolution contact displacement sensor (shown in FIG. 4) providing a high degree of accuracy in measurement of change in linear distance.

As shown in FIG. 4, the high-resolution contact displacement sensor 44 employs a high-intensity illumination from a point light source 44-1, specifically high luminance light emitting diode(s) (HL LED's), of a high-resolution Complementary Metal Oxide Semiconductor (CMOS) imaging element 44-2 through an absolute-value glass scale 44-3. The CMOS imaging element 44-2 in turn generates output signals with enhanced resolution. In general, the CMOS imaging element 44-2 is configured as an active-pixel sensor (APS), which is an image sensor in which each pixel sensor unit cell has a photo-detector and one or more active transistors. The contact displacement sensor is also equipped with a customized processor (not shown) having an algorithm configured to perform high-speed, high-resolution calculation of the output signals transmitted from the CMOS imaging element 44-2.

With resumed reference to FIG. 2, the test fixture 32 further includes a support or top plate 46 mounted to the reaction plate 36. Similar to the pressure plate 34 and the reaction plate 36, support plate 46 may be constructed from metal or an engineered plastic. The contact displacement sensor 44 may be mounted to the support plate 46. As shown in FIG. 2, the support plate 46 may define an aperture 48. In the particular embodiment, the contact displacement sensor 44 may include a probe 50 extending through the aperture 48 and contacting the pressure plate 34. As shown in FIGS. 3A and 3B, the load adjustment and locking screws 40A may extend threadably through the support plate 46. Additionally, as shown in FIGS. 3A and 3B, elastic members 39 of the elastic member assembly 38A may be disposed between the pressure plate 34 and the load plate 41. The elastic member assembly 38A may also include a retention plate 51 having a plurality of pockets 51A configured to accept a selectable or variable quantity of the elastic members 39, to thereby further adjust the applied force Fₚ. The retention plate 51 may be constructed from metal, such as aluminum, or an engineered plastic.

Alternatively, as shown in FIGS. 2 and 3C, the pneumatic mechanism 38B may include a plurality of air pistons 52 disposed between the pressure plate 34 and the support plate 46. The air pistons 52 may thus be configured to space the pressure plate 34 from the support plate 46 and regulate a distance D₁ there between. The pneumatic mechanism 38B may additionally include a display 53 configured to permit verification, in real time, of the value of air pressure applied to the air pistons 52. The test fixture 32 may additionally include a plurality of posts 54 configured to guide movement of the pressure plate 34 relative to the reaction plate 36. The posts 54 may additionally set a separation distance D₂ between the support plate 46 and the reaction plate 36 via an adjustable interface 56, such as via a threaded stud and nut connection (shown in FIG. 2).

As noted above and shown in FIGS. 2 and 3A, the system 30 may additionally include an environmental chamber 58 configured to position the test fixture 32 therein. The environmental chamber 58 is intended to maintain the test fixture 32 and components associated therewith at a specifically selected or predetermined temperature. As shown in FIG. 2, the environmental chamber 58 includes a control device 60, such as a thermostat, configured to vary or regulate temperature inside the chamber, and thereby expose the test fixture 32 to such a set temperature. The test fixture 32 and associated components are generally permitted time for temperature equilibration after any temperature changes via the control device 60. The environmental chamber 58 may be used to track changes in the battery thickness 10A, via the contact displacement sensor 44, at a number of different temperatures during a given test. As shown in FIGS. 2, 3A, and 3B, the environmental chamber 58 is also intended to include a temperature sensor 62 configured to detect tactual temperature T inside the chamber. The system 30 may further include an electronic controller 64 (shown in FIGS. 2, 3A, and 3B). The electronic controller 64 is configured, i.e., constructed and programmed, to regulate the system 30, and specifically the operation of the test fixture 32 and the environmental chamber 58.

The electronic controller 64 includes an electronic processor 66 and tangible, non-transitory memory, which includes instructions for operation of the test fixture 32 and the environmental chamber 58 programmed therein. The memory may be an appropriate recordable medium that participates in providing computer-readable data or process instructions. Such a recordable medium may take many forms, including but not limited to non-volatile media and volatile media. Non-volatile media for the electronic controller 64 may include, for example, optical or magnetic disks and other persistent memory. Volatile media may include, for example, dynamic random-access memory (DRAM), which may constitute a main memory. Such instructions may be transmitted by one or more transmission medium, including coaxial cables, copper wire and fiber optics, including the wires that comprise a system bus coupled to a processor of a computer, or via a wireless connection.

Memory of the electronic controller 64 may also include a flexible disk, hard disk, magnetic tape, another magnetic medium, a CD-ROM, DVD, another optical medium, etc. The electronic controller 64 may be configured or equipped with other required computer hardware, such as a high-speed clock, requisite Analog-to-Digital (A/D) and/or Digital-to-Analog (D/A) circuitry, input/output circuitry and devices (I/O), as well as appropriate signal conditioning and/or buffer circuitry. Algorithms required by the electronic controller 64 or accessible thereby may be stored in the memory and automatically executed to regulate operation of the environmental chamber 58 along with the test parameters for the test fixture 32 positioned therein. Necessary electrical connections between the electronic controller 64 and the test fixture 32 may be effectuated via appropriate electrical plugs (not shown).

As shown in FIG. 3B, the test fixture 32 may further include a load sensor 67 arranged to contact the battery cell holder 37 and configured to thereby detect the applied force Fₚ. The load sensor 67 is positioned on and may be mounted to the reaction plate 36. The electronic controller 64 may be in operative communication with each of the load sensor 67, the electronic hardware device 42, the contact displacement sensor 44, and the temperature sensor 62. In such an embodiment, the electronic processor 66 will be configured to receive a first signal 68 from the electronic hardware device 42 indicative of the applied electrical current I, a second signal 70A (shown in FIG. 3A) from the load sensor 67 or an alternative second signal 70B (shown in FIG. 2) from the pneumatic mechanism 38B (each being indicative of the applied force Fₚ), a third signal 72 from the contact displacement sensor 44 indicative of the detected battery thickness 10A, and a fourth signal 74 from the temperature sensor 62. The electronic processor 66 is further configured to generate a data file 76 representing, either in a numerical or a graphical format, a correlation between the applied electrical current I, the applied force Fₚ, and the detected battery thickness 10A, and the detected actual temperature T. The processor 66 may be in communication with a visual display device 78 to present the data file 76 for viewing and analysis.

The adjustable test fixture 32 may be portable. In other words, the adjustable test fixture 32 may be easily arranged and repositioned within its environment, including the environmental chamber 58. To facilitate ease of portability, the adjustable test fixture 32 may include one or more handles 80, as shown in FIGS. 3A and 3B. The handles 80 may be securely mounted to the support plate 46 to withstand the weight of the adjustable test fixture 32 being lifted via the subject handles.

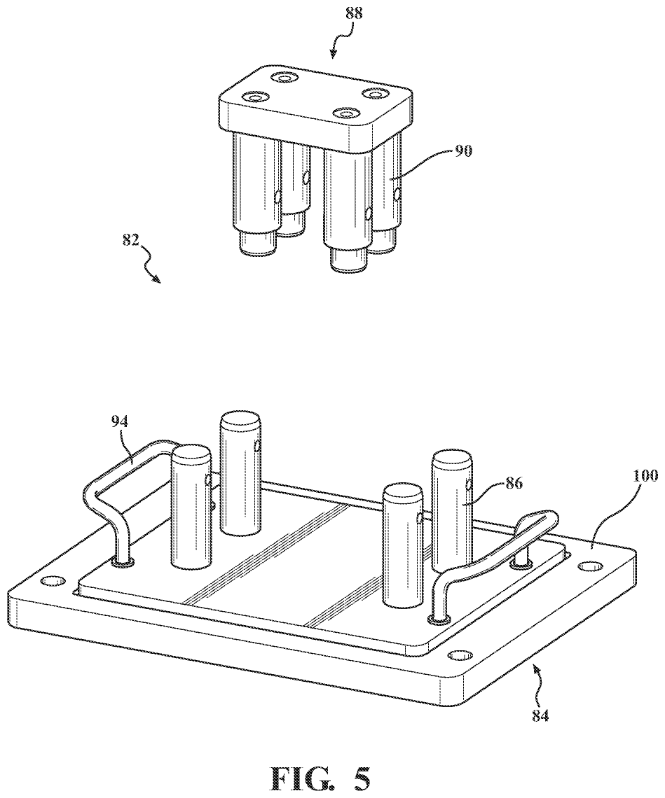

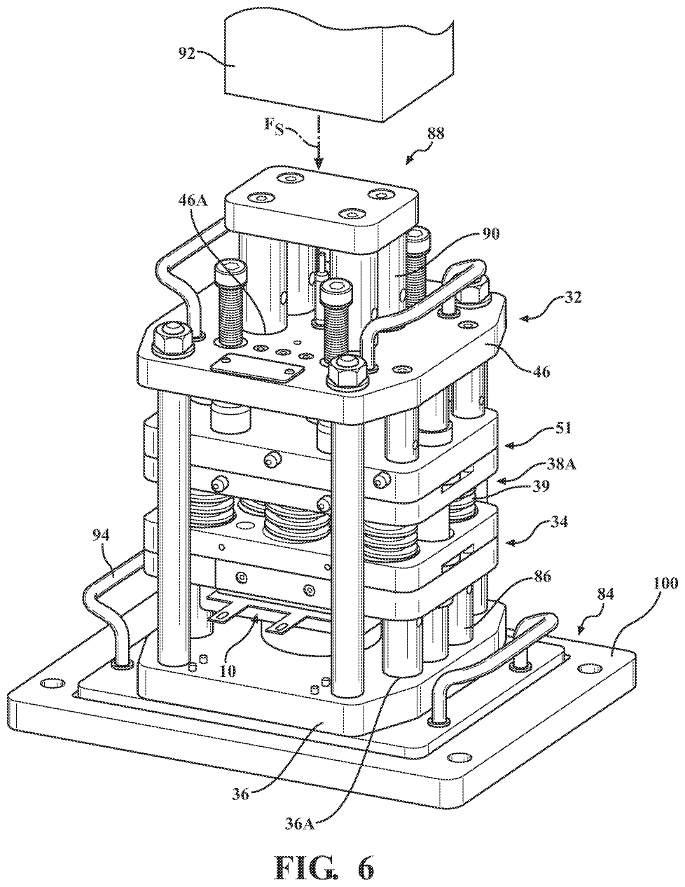

FIG. 5 illustrates a battery installation fixture 82 configured to facilitate removal and installation of the battery cell 10 into the test fixture 32 shown in FIGS. 3A and 3B. The battery installation fixture 82 includes a bottom assembly plate 84 having a plurality of upward extending posts 86, shown in the specific embodiment as four individual posts, operates in concert with a top assembly plate 88 having a plurality of downward extending posts 90, shown in the specific embodiment as four individual posts. As shown in FIG. 6, the test fixture 32 illustrated in FIGS. 3A and 3B may be arranged on the bottom assembly plate 84 with the upward extending posts 86 inserted through apertures 36A defined by the reaction plate 36 to contact the pressure plate 34.

With continued reference to FIG. 6, the top assembly plate 88 is intended to be arranged with the downward extending posts 90 inserted through apertures 46A defined by the support plate 46 to contact the retention plate 51. As shown in FIGS. 5 and 6, the battery installation fixture 82 may also include one or more handles 94, to facilitate assembly fixture repositioning and portability. As further shown in FIG. 6, a hydraulic press 92 may be used to apply a set-up force Fₛ to the top assembly plate 88, thereby countering the applied force Fₚ to shift the pressure plate 34 upward, toward the support plate 46. The set-up force Fₛ is intended to compress the elastic member(s) 39 and separate the pressure plate 34 and the battery cell holder 37, thus freeing up space to remove/install the battery cell 10.

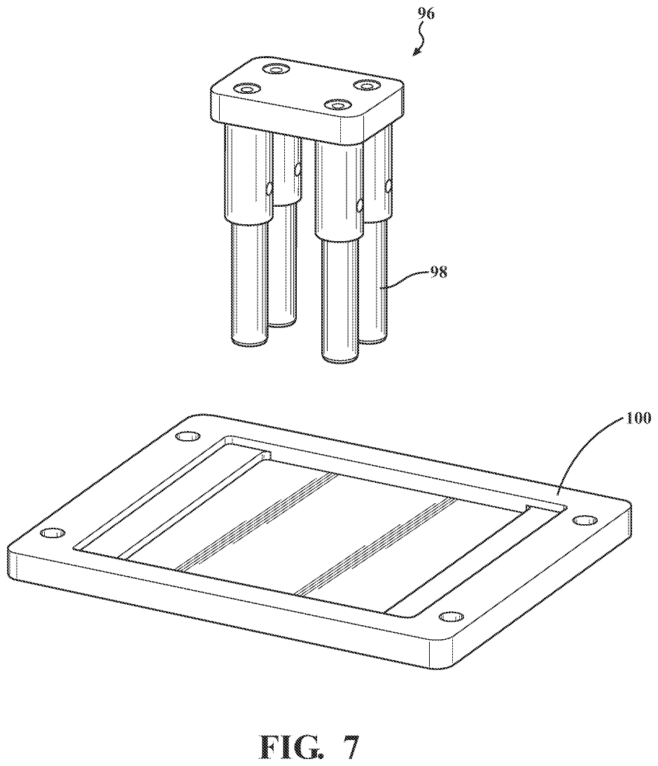

As shown in FIG. 7, a separate force-adjustment fixture 96 is provided to vary and preload compression of the elastic member(s) 39 and thereby adjust the applied force Fₚ of the test fixture 32 illustrated in FIGS. 3A and 3B. The force-adjustment fixture 96 includes a plurality of downward extending posts 98, shown in the specific embodiment as four individual posts. Once the battery cell 10 is installed into the battery cell holder 37, the force-adjustment fixture 94 may be arranged such that the downward extending posts 98 are inserted through apertures 46A defined by the support plate 46 to contact the load plate 41. The hydraulic press 92 may then be used to adjust the applied force Fₚ by compressing the elastic member(s) 39 via the load plate 41.

As the elastic member(s) 39 are being compressed, the second signal 70A from the load sensor 67 may be monitored until a desired or preset applied force Fₚ value has been achieved. Once the desired applied force Fₚ has been achieved, the load adjustment and locking screws 40A may be torqued to set the compression of the elastic member(s) 39 and maintain the applied force on the battery cell during its testing. The force-adjustment fixture 96 may be removed from the test fixture 32 to proceed with testing of the battery cell 10, such as when the test fixture is positioned inside the environmental chamber 58. As shown in FIGS. 5-7, each of the battery installation fixture 82 and the force-adjustment fixture 96 may be used in combination with a support stand 100 configured to position the test fixture 32 during the respective removal/installation of the battery cell 10 and adjustment of the applied force Fₚ described above.

The detailed description and the drawings or figures are supportive and descriptive of the disclosure, but the scope of the disclosure is defined solely by the claims. While some of the best modes and other embodiments for carrying out the claimed disclosure have been described in detail, various alternative designs and embodiments exist for practicing the disclosure defined in the appended claims. Furthermore, the embodiments shown in the drawings or the characteristics of various embodiments mentioned in the present description are not necessarily to be understood as embodiments independent of each other. Rather, it is possible that each of the characteristics described in one of the examples of an embodiment may be combined with one or a plurality of other desired characteristics from other embodiments, resulting in other embodiments not described in words or by reference to the drawings. Accordingly, such other embodiments fall within the framework of the scope of the appended claims.

What is claimed is:

1. A system for assessment of dimensional variation of an electro-chemical battery cell during charge/discharge cycling, the system comprising:
a test fixture configured to position thereon a battery cell defined by a battery thickness, the test fixture having:
a pressure plate configured to apply a force to the battery cell;
a reaction plate disposed parallel to the pressure plate and configured to sandwich the battery cell between the reaction plate and the pressure plate;
an elastic member assembly configured to facilitate adjustment of the force applied, via the pressure plate, to the battery cell;
an electronic hardware device configured to regulate an electrical current applied to the battery cell; and
a contact displacement sensor configured to detect change in the battery thickness.

2. The system of claim 1, further comprising a support plate mounted to the reaction plate, and wherein the contact displacement sensor is mounted to the support plate.

3. The system of claim 2, wherein the support plate defines an aperture, and wherein the contact displacement sensor includes a probe extending through the aperture and contacting the pressure plate.

4. The system of claim 2, wherein the test fixture additionally includes a plurality of posts configured to set a separation distance between the support plate and the reaction plate and guide movement of the pressure plate relative to the reaction plate.

5. The system of claim 2, wherein the elastic member assembly includes a retention plate having a plurality of pockets configured to accept a variable quantity of elastic members and thereby adjust the applied force.

6. The system of claim 2, wherein the elastic member assembly includes a plurality of coil springs disposed between the pressure plate and the support plate.

7. The system of claim 1, wherein the electronic hardware device includes a potentiostat.

8. The system of claim 1, further comprising a load sensor configured to detect the applied force and an electronic processor configured to:
receive a first signal from the electronic hardware device indicative of the applied electrical current, a second signal from the load sensor indicative of the applied force, and a third signal from the contact displacement sensor indicative of the detected battery thickness; and
generate a data file representing a correlation between the applied electrical current, the applied force, and the detected battery thickness.

9. The system of claim 8, further comprising an environmental chamber configured to position the test fixture therein and expose the test fixture to predetermined temperature and having a temperature sensor configured to detect actual temperature inside the environmental chamber.

10. The system of claim 9, wherein the electronic processor is additionally configured to receive a fourth signal from the temperature sensor such that the generated data file additionally represents a correlation between the applied electrical current, the applied force, the detected battery thickness, and the detected actual temperature.

11. A test fixture for assessment of dimensional variation of an electro-chemical battery cell during charge/discharge cycling, the test fixture comprising:
a test fixture configured to position thereon a battery cell defined by a battery thickness, the test fixture having:
a pressure plate configured to apply a force to the battery cell, wherein the battery cell has a battery thickness;
a reaction plate disposed parallel to the pressure plate and configured to sandwich the battery cell between the reaction plate and the pressure plate;
an elastic member assembly configured to facilitate adjustment of the force applied, via the pressure plate, to the battery cell;
an electronic hardware device configured to regulate an electrical current applied to the battery cell; and
a contact displacement sensor configured to detect change in the battery thickness.

12. The test fixture of claim 11, further comprising a support plate mounted to the reaction plate, and wherein the contact displacement sensor is mounted to the support plate.

13. The test fixture of claim 12, wherein the support plate defines an aperture, and wherein the contact displacement sensor includes a probe extending through the aperture and contacting the pressure plate.

14. The test fixture of claim 12, further comprising a plurality of posts configured to set a separation distance between the support plate and the reaction plate and guide movement of the pressure plate relative to the reaction plate.

15. The test fixture of claim 12, wherein the elastic member assembly includes a retention plate having a plurality of pockets configured to accept a variable quantity of elastic members and thereby adjust the applied force.

16. The test fixture of claim 12, wherein the elastic member assembly includes a plurality of coil springs disposed between the pressure plate and the support plate.

17. The test fixture of claim 11, wherein the electronic hardware device includes a potentiostat.

18. A system for assessment of dimensional variation of an electro-chemical battery cell during charge/discharge cycling, the system comprising:
a test fixture configured to position thereon a battery cell defined by a battery thickness, the test fixture having:
a pressure plate configured to apply a force to the battery cell;
a reaction plate disposed parallel to the pressure plate and configured to sandwich the battery cell between the reaction plate and the pressure plate;
an elastic member assembly configured to facilitate adjustment of the force applied, via the pressure plate, to the battery cell;
an electronic hardware device configured to regulate an electrical current applied to the battery cell;
a contact displacement sensor configured to detect change in the battery thickness; and
a load sensor configured to detect the applied force;
an environmental chamber configured to position the test fixture therein and expose the test fixture to predetermined temperature and having a temperature sensor configured to detect actual temperature inside the environmental chamber; and
an electronic processor configured to:
receive a first signal from the electronic hardware device indicative of the applied electrical current, a second signal from the load sensor indicative of the applied force, a third signal from the contact displacement sensor indicative of the detected battery thickness, and a fourth signal from the temperature sensor indicative of the detected actual temperature; and
generate a data file representing a correlation between the applied electrical current, the applied force, the detected battery thickness, and the detected actual temperature.

19. The system of claim 18, further comprising a support plate mounted to the reaction plate via a plurality of posts, and wherein:
the contact displacement sensor is mounted to the support plate;
the support plate defines an aperture;
the contact displacement sensor includes a probe extending through the aperture and contacting the pressure plate; and
the plurality of posts is configured to set a separation distance between the support plate and the reaction plate and guide movement of the pressure plate relative to the reaction plate.

20. The system of claim 19, wherein the elastic member assembly includes:
a plurality of pockets configured to accept a variable quantity of elastic members configured to adjust the force applied by the elastic member assembly; and
a plurality of coil springs disposed between the pressure plate and the support plate.
